(19) United States
(12) Patent Application Publication
(10) Pub. No.: US 2009/0130821 A1
(43) Pub. Date: May 21, 2009

(54) THREE DIMENSIONAL PACKAGING WITH WAFER-LEVEL BONDING AND CHIP-LEVEL REPAIR

(75) Inventors: Damon K. Cox, Round Rock, TX (US); Todd J. Egan, Fremont, CA (US); Michael X. Yang, Palo Alto, CA (US); Jeffrey C. Hudgens, San Francisco, CA (US); Ingrid B. Peterson, Menlo Park, CA (US); Michael R. Rice, Pleasanton, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(73) Assignee: Applied Materials, Inc., Santa Clara, CA (US)

(21) Appl. No.: 12/249,812

(22) Filed: Oct. 10, 2008

Related U.S. Application Data
(60) Provisional application No. 60/979,481, filed on Oct. 12, 2007.

(51) Int. Cl. H01L 21/30; G06F 17/50

(52) U.S. Cl. 438/455; 716/2; 156/538; 156/379.8; 257/E21.598

(57) ABSTRACT

A method, a system and a computer readable medium for three dimensional packaging with wafer-level bonding and chip-level repair. A first wafer is provided having a first plurality of chips. A second wafer is provided having a second plurality of chips. At least one chip is removed from the second wafer while retaining the relative alignment of the remaining chips in the second wafer. The first and second wafers are aligned and joined with wafer-to-wafer techniques. Where a bad chip having a relative physical position within the second wafer corresponding to a relative physical position within the first wafer of a good chip is removed, a good chip may be aligned and bonded to the first wafer using die-to-wafer techniques.

### CROSS REFERENCE TO RELATED APPLICATIONS

This application claims the benefit of U.S. Provisional Application No. 60/979,481, filed Oct. 12, 2007, the entire contents of which are hereby incorporated by reference herein.

### BACKGROUND OF THE INVENTION

### 1) Field of the Invention

The invention is in the field of Semiconductor Processing.

### BRIEF DESCRIPTION OF THE DRAWINGS

FIG. 1 is a flowchart depicting operations for three-dimensional packaging, in accordance with an embodiment of the present invention.

FIG. 2A is a plan view illustrating a first wafer for chip-to-wafer bonding, in accordance with an embodiment of the present invention.

FIG. 2B is a plan view illustrating a second wafer for chip-to-wafer bonding, in accordance with an embodiment of the present invention.

FIG. 2C is a plan view illustrating chip-level removal of chips from the second wafer, in accordance with an embodiment of the present invention.

FIG. 2D is an isometric view illustrating wafer-level alignment and bonding of a first wafer to a second wafer in accordance with an embodiment of the present invention.

FIG. 2E is an isometric view illustrating chip-level fill of a wafer after chip-level removal, in accordance with an embodiment of the present invention.

FIG. 3A is a plan view illustrating a segmented chuck having a plurality of independently controllable chucking zones, in accordance with an embodiment of the present invention.

FIG. 3B is a plan view illustrating a wafer on a segmented chuck, in accordance with an embodiment of the present invention.

FIG. 4 is a plan view illustrating a system configurable to vertically integrate chips at the wafer-level with chip-level removal, in accordance with an embodiment of the present invention.

### DETAILED DESCRIPTION

A method and system for three dimensional packaging with wafer-level bonding and chip-level repair are described herein. In the following description, numerous specific details are set forth, such as order of operations, in order to provide a thorough understanding of the present invention. It will be apparent to one skilled in the art that the present invention may be practiced without these specific details. In other instances, well-known features, such as specific bonding techniques, are not described in detail in order to not unnecessarily obscure the present invention. Furthermore, it is to be understood that the various embodiments shown in the Figures are merely illustrative representations and are not necessarily drawn to scale.

Disclosed herein are a method and a system for wafer-level (i.e., “wafer-to-wafer”) bonding with the ability to bond known good chips of one wafer selectively to known good chips of a second wafer. The method employs wafer-level bonding to utilize the chip-to-chip relative alignment present among the chips fixed within a single wafer, thereby enabling high throughput bonding of the chips of one wafer to the chips of another wafer for applications such as three-dimensional packaging. Such wafer-to-wafer alignment and bonding techniques may provide high throughput with tight alignment tolerances. For example, on the order of 1000 chips/hour at 1 μm misalignment tolerance. However, in particular embodiments described herein, the wafer-to-wafer bond between a first and second wafer is performed in a manner to avoid bonding a bad chip of a first wafer (e.g. failing functional test) with a good chip of the second wafer (e.g. passing functional test), or visa versa, to maximize the cumulative yield of the chip-chip package. The method and system may further utilize chip-level removal to selectively remove individual chips from at least the second wafer while retaining the relative positions of the wafer's remaining chips. With individual chips physically removed from the second wafer, the second wafer is joined to the first wafer with wafer-level alignment and wafer-level bonding to bond known good chips of the first wafer to known good chips of the second wafer. Wafer-to-wafer alignment and wafer-to-wafer bonding techniques may be employed to align and bond the remaining chips to the first wafer because the fixed relative positions of the remaining chips of the second wafer are retained after removal of the individual chips.

Because selective chip-level removal of individual chips may prevent good chips on the first wafer from being bonded to bad chips of the second wafer, the yield of the wafer-level bonding may be increased. To further increase packaging yield, in particular embodiments, individual good chips not bonded at the wafer-level may then be aligned and bonded at the chip-level (i.e., with “chip-to-wafer” techniques) to “fill” in the regions where bad chips were removed from the second wafer. Such chip-level removal and fill combine for a chip-level “repair” of wafers aligned and bonded at the wafer-level.

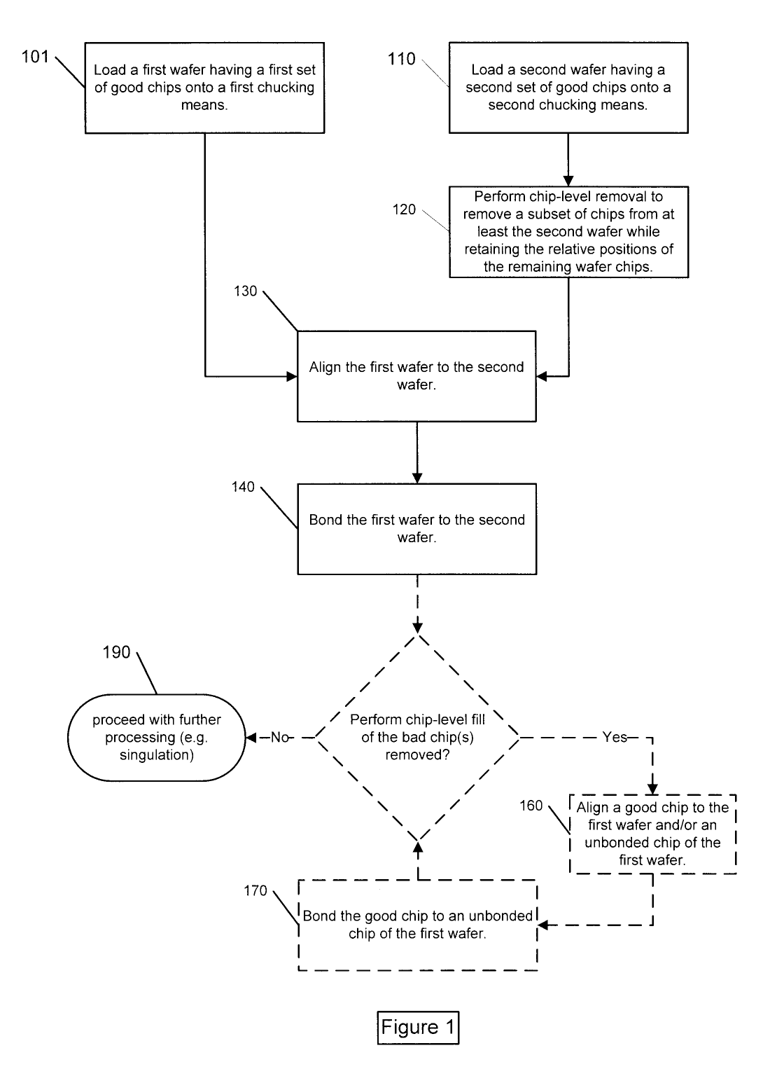

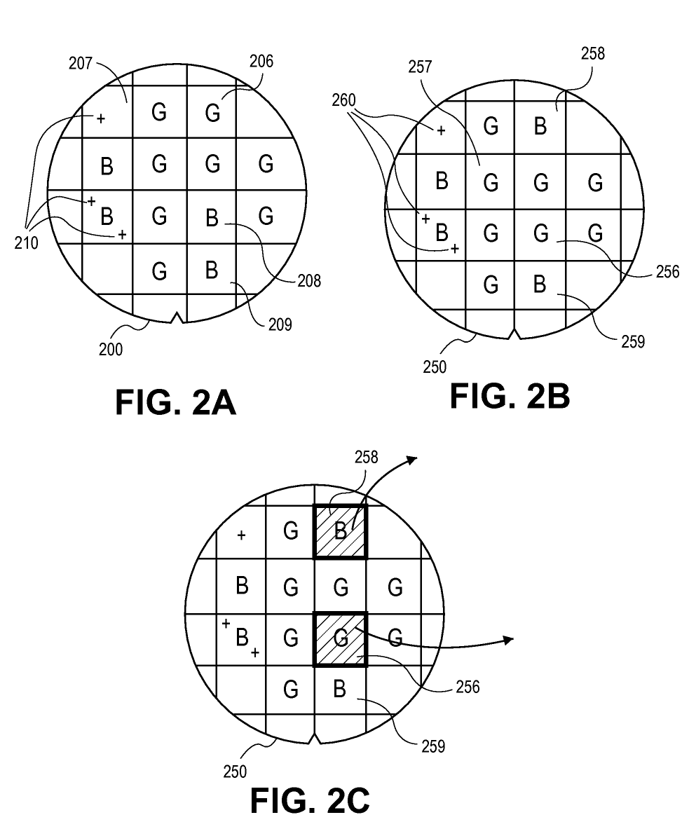

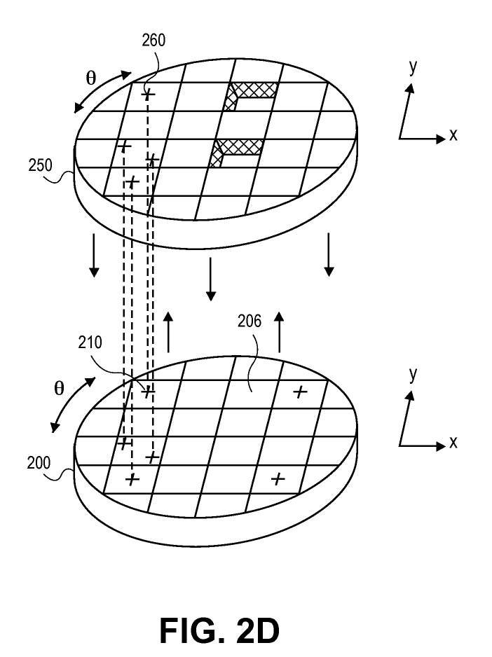

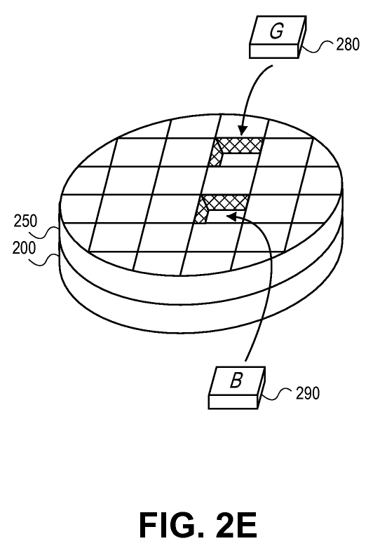

As shown in FIG. 1, an embodiment of the method includes loading a first wafer having known good chips onto a first chuck at operation 101. As provided, all chips on both the first and second wafer are mapped by relative position within the wafer (e.g. x-y coordinates) and identified as “good” or “bad.” In one embodiment, the known good chips are those that satisfied a previous wafer-level parametric and/or functional test. For example, the first wafer may be wafer 200, as further shown in FIG. 2A in a plan view. For illustrative purposes, each known good chip, such as the known good chips 206 and 207, are labeled “G” in FIG. 2A. Each known good chip is at a known position and has fixed alignment within the wafer 200. For example, the position of known good chip 206 may be identified as row one and column three, or (1, 3) and alignment to a feature anywhere on the wafer 200 will align the known good chip 206. Similarly, the remaining bad chips, such as bad chip 208 are labeled “B” in FIG. 2A, for illustrative purposes.

Referring back to the embodiment of FIG. 1, at operation 110, a second wafer having known good chips is loaded onto a second chuck. For example, the second wafer may be wafer 250, as further shown in FIG. 2B in a plan view. Here also, each known good chip, such as the known good chips 256 and 257, are labeled “G.” Each known good chip is at a known position and fixed alignment relative to the wafer 250. The remaining bad chips, such as bad chip 258, are labeled “B,” and have similarly known relative positions and a fixed alignment relative to other locations on the wafer 250. In the specific embodiment depicted, the wafers 200 and 250 each further include wafer-level alignment marks 210 and 260, respectively, located at an inter-chip scribe-line. In other embodiments, alignment marks are provided within the one or more chips of wafers 200 and 250.

Wafers 200 and 250 may be any wafers onto which a chip will be bonded. For example, in accordance with particular embodiments of the present invention, wafers 200 and 250 are comprised of semiconductor chips having interconnect lines exposed at the top or bottom surfaces of wafers 200 and 250. The wafers may be commonly known substrate material, such as, but not limited to, silicon, III-V compound semiconductors, II-V semiconductors, sapphire and polymers. The chips on the wafers may include any commonly known device, such as, but not limited to, microelectronic, electro-optical, biochemical devices.

The first and/or second chuck may be any chuck or stage which can hold the first and/or second wafer. In one embodiment, the chuck includes an electrostatic chuck. In another embodiment, the chuck includes a vacuum chuck to hold the wafer to the chuck. In yet another embodiment, the chuck includes an adhesive surface, such as a tape, to hold the wafer to the chuck. In still another embodiment, the chuck includes a clamp to hold the wafer to the chuck. Depending on the manner in which the two wafers are to be bonded, the chuck may be configured to hold either side of the wafer. In a further embodiment, the chuck is configured to facilitate selective removal of individual chips from the wafer. In particular, the chuck may have grooves coincident with the scribe lines between chips of the wafer to assist a cutting operation, or the chuck may include a sacrificial layer which can be replaced after a cutting operation.

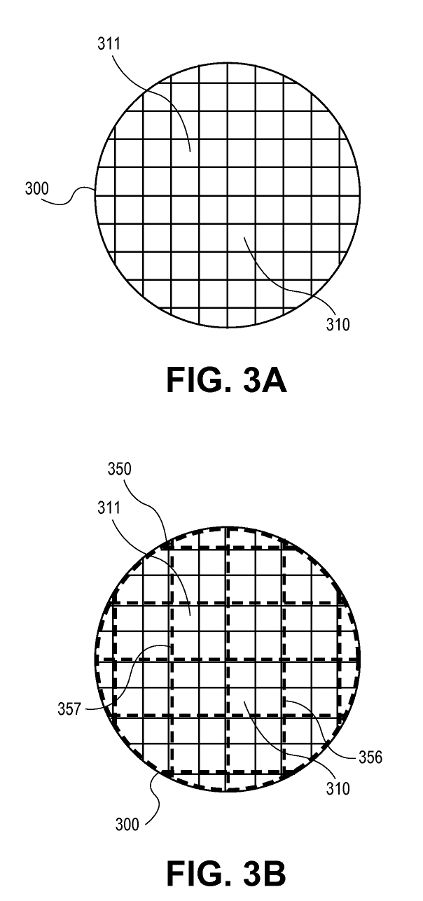

In a particular embodiment, the chuck is zoned into individual regions capable of selectively holding and releasing individual zones of the chuck. In one such embodiment, the chuck is segmented in a manner to have individual zones positioned across the chuck to provide holding/releasing forces at the chip-level. In one such embodiment, the chuck is segmented in a manner to have individual zones positioned across the chuck, each individual zone being physically smaller than each of the chips of the wafer loaded on it. For example, as shown in FIG. 3A, segmented chuck 300 includes a plurality of independently controllable zones (e.g. 310 and 311) arranged in a grid pattern across the chuck. Each of the plurality of independently controllable zones providing a means to hold a single chip of a wafer. In another embodiment, the area of each independently controllable zone is significantly smaller than the chip area and the density of the individual zones is significantly larger than the chip density to make wafer placement on the chuck less critical. In one such embodiment, the segmented chuck has between two and four zones within an area equal to that of a chip in the wafer held by the chuck.

An exemplary implementation is depicted in FIG. 3B. Here, a plan view of wafer 250 of FIG. 2B is positioned over a plan view of the segmented chuck 300 of FIG. 3A to represent wafer 350 loaded on segmented chuck 300. In this particular embodiment, the independently controllable zone 310 provides a force to hold the single chip 356 of a wafer 350 while the independently controllable zone 311 provides a force to hold the single chip 357 of a wafer 350. In particular embodiments, each independently controllable zone provides an independent vacuum means or electrostatic means to hold regions of the wafer in an independently controllable manner. When a wafer, such as wafer 350, is loaded onto the segmented chuck 300, one or more of the independently controllable chucking zones may selectively hold and release portions of the wafer corresponding to relative positions of chips of the wafer. In still another embodiment, segmented chuck 300 comprises a plurality of physically independent units capable of independent chucking as well as independent movement.

Returning to FIG. 1, at operation 120, selective chip-level removal is performed. Here, individual chips are selected and removed from at least the second wafer while retaining the fixed relative position and alignment among the chips remaining in the wafer. Because the chip removal is selective at the chip-level, chips remaining after the removal operation 120 may be aligned and bonded to the chips of the first wafer at a wafer-level using a global alignment and bonding process adapted for entire wafers.

Which wafer is selected as the “first” and “second” wafer is an implementation detail. In certain embodiments where one wafer is substantially thicker (e.g. hundreds of mils) than the other wafer (e.g. 25 mils), the removal operation is performed on the thinner wafer to simplify cutting a chip from the wafer. Thus, in such an embodiment the “second” wafer is a wafer thinner than the first wafer. In another embodiment, where the yield is substantially higher in a first wafer than another and the removal operation is performed on the lower yielding wafer, the “second” wafer is the lower yielding wafer. In particular yield-based embodiments, the first and second wafer are sorted from a population of candidate wafers to be packaged to optimize a match of the yield patterns of two wafers to be bonded. Such sorting may be done based on the number of bad chips on a wafer and the relative positions of the bad chips to maximize the match between bad chips in the first wafer with bad chips in the second wafer to reduce yield fallout of the wafer-level bonding. Fewer chips then require chip-level removal. In still other embodiments, a removal operation is performed on both the first and second wafer to be bonded.

In a particular embodiment, at least one bad chip of the second wafer which has a relative position within the second wafer corresponding to a relative position of a good chip in the first wafer is selectively removed. For example, referring to FIGS. 2A and 2B, for a bonding arrangement where the back side of the wafer 250 is to be stacked on the front side of the wafer 200, the bad chip 258 has a relative position within the wafer 250 of row one, column three (1,3) corresponding to the relative position of good chip 206 at (1,3) within the wafer 200. To avoid spoiling the good chip 206 by pairing it with the bad chip 258, the bad chip 258 is removed from the wafer 250, as shown in FIG. 2C. In further embodiments, all such bad chips having relative positions within the wafer 250 corresponding to locations of good chips 205 within the wafer 200 are selectively removed to prevent bonding any bad chip of wafer 250 to the wafer 200. In still another embodiment, at least one bad chip within the first wafer having a relative position within the first wafer corresponding to a relative position of a good chip in the second wafer is selectively removed. In a particular embodiment, a least one bad chip within each of the first and second wafer having a physical location corresponding to a physical locations of good chip within the alternate wafer are removed at operation 120.

In a further embodiment, at least one good chip in the second wafer having a relative physical position within the second wafer corresponding to a relative physical position of a bad chip in the first wafer is selectively removed. For example, referring to FIGS. 2A and 2B, for a bonding arrangement where the back side of the wafer 250 is to be stacked on the front side of the wafer 200, the good chip 256 has a relative position of (3,3) within the wafer 250 corresponding to the relative position of bad chip 208 (3,3) within the wafer 200. To avoid spoiling the good chip 256 by pairing it with the bad chip 208, the good chip 256 is removed from the wafer 250, as further shown in FIG. 2C. In particular embodiments, all such good chips having relative positions within the wafer 250 corresponding to the location of bad chips within the wafer 200 are removed to prevent bonding any bad chip to the wafer 200.

In a particular embodiment, both a bad chip of the second wafer having a relative position within the second wafer corresponding to a relative position of a good chip in the first wafer (e.g. 258) and a good chip in the second wafer having a relative physical position within the second wafer corresponding to a relative physical position of a bad chip in the first wafer (e.g. 208) are selectively removed. Thus, as shown in FIG. 2C, both bad chip 258 and good chip 256 are removed from wafer 250. In this embodiment, the cumulative yield of bonding the first wafer to the second wafer may be significantly improved by removing chips from the second wafer while leaving the first wafer unaltered.

In still another embodiment, selective removal excludes a bad chip of the second wafer having a relative position within the second wafer corresponding to a relative position of a bad chip in the first wafer. Since both chips to be bonded upon a joining of the first and second wafer are bad, further yield loss is not incurred. For example, bad chip 259 is retained in the wafer 250 after the removal operation 120 to be subsequently bonded to bad chip 209 when the wafer 250 is bonded to the wafer 200. After singulating the bonded chips, the bad chips of the second substrate bonded to bad chips of the first substrate may be discarded. For such embodiments, retention of the bad chip-bad chip pairings may improve the uniformity of the bonding process characteristics, such as planarity, thermal conditions, stress, etc. As used herein, “singulating” is a process by which a single chip is separated from neighboring chips by severing the substrate along a perimeter of the chip (e.g., dicing) such that a “singulated chip” is then individually removable from the plurality of chips which formally comprised a wafer. For example, where two or more wafers are joined, singulating results in individual bonded multi-chip units.

As previously mentioned, chips remaining within the second wafer retain the alignment and positional information contained in an “un-sawed” wafer after the selective removal operation 120 so that the remaining chips may still be aligned and bonded as a unit to the first wafer using wafer-level techniques. In particular embodiments, physical integrity of the wafer ensures the remaining chips have a fixed relative position and alignment that enables all remaining chips to be aligned and bonded as a single population. For example, referring to FIG. 2C, removal of both bad chip 258 and good chip 256 leaves a continuous wafer 250 having two openings or “windows.” The physical continuity of wafer 250 retains the relative position and alignment of the remaining chips so they may be aligned and/or bonded as a unit with wafer-level alignment and bonding techniques rather than as a plurality of subsets which must each be aligned and bonded iteratively as done in chip-to-wafer bonding. In one embodiment, where the chips removed are individual chips comprising less than 10% of the possible chips, physical integrity is maintained through the remaining chips. In another embodiment, physical integrity is maintained after selective chip removal along a circumference of the wafer, where no chips are good in either the first or second wafer. In yet another embodiment, the number of chips physically removed during the removal operation 120 is pre-determined to ensure physical continuity between the chips remaining in the second wafer after the removal operation 120.

In an alternative embodiment, the relative position and alignment information of the chips remaining after the removal operation 120 is retained by maintaining a chucking force from prior to the removal operation 120 to a subsequent bonding operation. Maintaining a chucking force may help to retain the physical integrity of a wafer after selective chip removal or otherwise retain the fixed relative positions and alignment of the remaining chips. In certain embodiments where the wafer is very thin and/or many chips are removed the wafer may lose structural rigidity or physical continuity. For example, a donut-shaped chip removal pattern may leave some singulated chips. In certain other embodiments, the wafer may be diced to form completely singulated chips. Nonetheless, in particular embodiments where a substantially continuous chucking force is maintained on various portions of the wafer before and after the removal operation 120 or a dicing operation, the relative positional and alignment information present in the continuous wafer may be retained. Referring back to FIG. 3B, in the situation where removal of the single chip 356 causes chip 357 to lose physical continuity with other remaining chips, upon removal of chip 356, independently controllable zone 311 maintains a holding force to preserve the relative position and alignment of chip 356.

The removal operation 120 includes a removal means including a cutting means and a picking means. In a particular embodiment, the cutting means employed is capable of cutting a path about a perimeter of a single chip in one or more places on a wafer. As shown in FIG. 2C, a cutting means circumscribes chips either individually or continuously, serially or in parallel, to be individually removable from the second wafer. The cutting means may include, but is not limited to, a saw, a grinding wheel, a water jet, a laser and any other means for singulating a chip from a wafer as commonly known in the art. The picking means includes, but is not limited to, a robotic arm fitted with a vacuum pick, such as those commonly employed for a pick and place packaging operations.

Returning to FIG. 1, at operation 130, while the first and second wafers are held by a chuck, the second wafer, such as the wafer 250, may be aligned to the first wafer, such as wafer 200, by any method suitable to provide substantial translational and rotational alignment between the wafers. Because the relative position and alignment of the remaining chips of the second wafer have been retained, a single alignment process will align all remaining chips within wafer 2 just as if no chips had been removed. In accordance with an embodiment of the present invention, wafer 250 is aligned to wafer 200 by aligning the alignment mark(s) 260 to the alignment mark(s) 210, as shown in FIG. 2D. In one embodiment, wafer 250 is aligned to the wafer 200 by an alignment technique selected from the group consisting of optical transparency alignment, IR transmission alignment, wafer-back-side alignment, through-wafer hole alignment, microscope alignment and face-to-face alignment. As shown, wafer 200, wafer 250 or both wafers may have rotational and/or translational motion during alignment. In a specific embodiment, the wafer 250 is aligned to the wafer 200 by aligning the alignment mark 260 with the alignment mark 210 with an overlap error margin of at most 1 μm. In certain other embodiments, the alignment operation is performed prior to selective removal of any chip from the second wafer.

After aligning the first wafer to the second wafer, the two wafers, while held by their respective chuck, are bonded at operation 140 to integrate the chips of each wafer as shown in FIG. 2E. The joining of the first and second wafers, after being aligned once, then ensures all chips of the bonded wafers are sufficiently aligned. The bonding operation 140 may serve to permanently or temporarily join the two wafers, such as wafers 200 and 250. For embodiments with temporary bonding, the joined wafers may be subsequently processed to form a permanent bond.

In particular embodiments, prior to bonding, a “dummy fill” is performed in where good chips are removed from the second wafer because they correspond to bad chips in the first wafer. In such embodiments, the voids formed in the second wafer are filled in with individual (i.e., singulated) bad chips or dummy chips using minimal alignment (i.e., relatively large misregistration tolerance). In the embodiment depicted in FIG. 2E, the bad chip 290 is roughly aligned and bonded to the wafer 200. The bad chip-bad chip pair formed may be subsequently discarded after the bonded wafers are singulated. The presence of the individually bonded bad chip 290 may provide for improved thermal and mechanical uniformity during a bonding process.

The bonding operation 140 may employ any method suitable to provide substantial mechanical bonding between the first and second wafer. In accordance with an embodiment of the present invention, wafer 200 is bonded to wafer 250 by a method that provides both mechanical and electrical bonding. In one embodiment, wafer 200 is bonded to wafer 250 by a method selected from the group consisting of dielectric bonding, adhesive bonding, copper bonding, solder bonding, eutectic bonding, and metal/adhesive redistribution layer bonding. Particular temporary bonding embodiments include joining the wafers with an electrostatic force to hold the two wafers together. In a specific embodiment, wafer 200 is bonded to wafer 250 at a temperature of less than approximately 400° C. In a particular embodiment, through vias in wafer 250 are bonded to interconnect lines on the surface of wafer 200. In another particular embodiment, interconnects on a top surface of wafer 250 are bonded to interconnects on a top surface of wafer 200 (not shown). After either permanent or temporary bonding of the first wafer to the second wafer, the bond provides a holding force sufficient that at least one of the chucks may be removed to free a surface of the bonded wafer pairs.

As shown in FIG. 1, following the bonding operation 140, the stacked wafer pair may further receive a chip-level fill or be transported as a unit to other operations in the packaging process, such as wafer dicing at operation 190. For embodiments not employing a chip-level fill, the cumulative yield may be improved relative to wafer-level bonding alone by the number of both good and bad chips removed at operation 120. Individual good chips removed (e.g. good chip 256) are recovered immediately and individual unbonded good chips (e.g. good chip 206 in FIG. 2D) corresponding to bad chips removed may be recovered after the dicing operation. Thus, no chips need be lost while the advantages of wafer-level bonding are achieved.

For chip-level fill embodiments, chip-level alignment and bonding is performed at operation 160 of FIG. 1. Singulated good chips are aligned on an individual basis to either the first wafer or second wafer to fill the void created by removing bad chips from the second wafer, as further shown in FIG. 2E. For such embodiments employing chip-level fill, the cumulative bonded wafer yield is further improved relative to conventional wafer-level bonding. Chip-level fill embodiments can make use of the recovered good die resulting from the selective removal operation through an application of chip-to-wafer alignment and bonding techniques.

In certain chip-level fill embodiments, a good chip is aligned at operation 160 and bonded at operation 170 to the first wafer after the second wafer is either permanently or temporarily bonded to the first wafer at operation 140. In the embodiment shown in FIG. 2E, good chip 280 is aligned to the chip in the unbonded region of wafer 200 corresponding to the relative physical location of bad chip 258 in wafer 250. Good chip 280 may be any chip suitable for bonding with wafer 200. For example, in accordance with an embodiment of the present invention, good chip 280 is a semiconductor chip having an alignment mark thereon. In a further embodiment, good chip 280 is a good chip removed from another location of wafer 250, such as good chip 256.

The chip-to-wafer alignment and bonding performed at operations 160 and 170 may be performed using conventional techniques, such as those described elsewhere herein for wafer-level alignment and bonding or it may be an accelerated alignment and bonding method. One particular accelerated alignment method includes: aligning a gantry with the wafer 200 to provide a pre-aligned gantry; aligning the good chip 280 with the pre-aligned gantry to provide a gantry-aligned chip; and bonding the gantry-aligned chip to the wafer 200. Upon alignment, good chip 280 is permanently or temporarily bonded to wafer 200 thereby filling in the location in wafer 250 vacated by bad chip 258. In this manner the bonded wafer pair is “repaired” at the chip-level. In certain embodiments where bad chips are removed from both the first and second wafer, good chips may be aligned and bonded to both the first and second wafer to provide for bonded wafers having up to 100% yield. In an alternate chip-level repair embodiment (not shown) the good chips are aligned on an individual basis to the second wafer prior to bonding the second wafer to the first wafer at operation 140. The good chip, once aligned to the second wafer, is held in position with a chuck, such as one of those described elsewhere herein.

For wafers having chips of dissimilar size, the same wafer-level alignment/bonding with chip-level repair may be performed for embodiments where the chip density of the second wafer with the smaller chip is reduced and the relative positions of the smaller chips on the first wafer are predetermined to correspond with the relative positions of the larger chips on the second wafer. In an alternate embodiment, a carrier frame may be used to hold a portion of the smaller die and the carrier frame is then aligned to the first wafer.

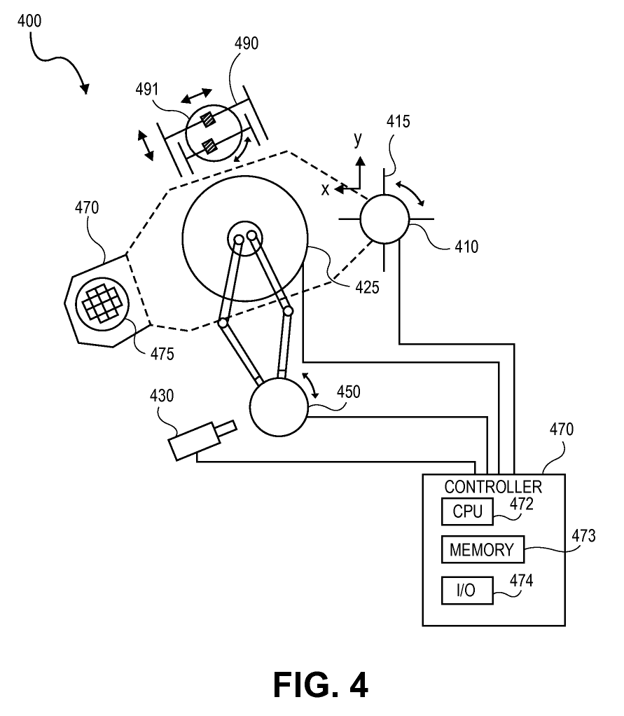

Referring to FIG. 4, a wafer-to wafer bonding system 400, configurable for chip-level removal and fill, comprises a first chuck 410 and a second chuck 450. The first chuck 410 and/or the second chuck 450 may be similar to a segmented chuck 300 described elsewhere herein. In the embodiment depicted, the second chuck 450 is coupled to a robotic handler 425. During operation, robotic handler 425 may acquire a wafer, such as the wafer 475, from another location, such as the pre-load station 470. The robotic handler 425 may further include an alignment means to align the chuck 450 to the wafer 475. The system 400 further includes a cutting means 430, such as those described elsewhere herein, to remove chips from a wafer. The system 400 may robotically move either a wafer on the second chuck 450 or the cutting means 430 to remove chips from a wafer held by the chuck 450. Following a removal of chips, the robotic handler 425 may position the remaining chips of the wafer, held with fixed relative position and alignment by the second chuck 450, on a wafer held by the first chuck 410. In an embodiment, system 400 further includes a wafer-to-wafer alignment means 415 coupled with first chuck 410 to align to the wafer held by the second chuck 450. In an embodiment, the first chuck 410 and second chuck 450 further serve as a bonding means to join a first and second wafer.

System 400 may further include a chip-level alignment means and chip-level bonding means 490 configurable to perform chip-level fill, as described elsewhere herein. In the embodiment shown, the chip-level bonding means 490 includes a plurality of gantries to which individual chips are first aligned and the gantry further aligned with a wafer held by third chuck 491. In an embodiment, the robotic handler 425 transfers joined wafers at the first chuck 410 to the third chuck 491 for chip-level fill. System 400 may further include a final bonding station and/or a dicing station for singulating the three-dimensionally integrated chips.

In an embodiment of the present invention, system 400 is computer controlled by controller 470 to control wafer handler 425, wafer-to-wafer alignment means 415, wafer-to-wafer bonding means (e.g., chuck 410 and 450), cutting means 430 and chip-level bonding means (e.g., 490 and 491). Controller 470 may be one of any form of general-purpose data processing system that can be used in an industrial setting for controlling the various subprocessors and subcontrollers. Generally, controller 470 includes a central processing unit (CPU) 472 in communication with memory 473 and input/output (I/O) circuitry 474, among other common components. Software commands executed by CPU 472, cause system 400 to perform a computer implemented method, such as chucking a wafer, removing chips while maintaining the relative physical locations and fixed alignment of the remaining chips in the first wafer, performing a wafer-to-wafer alignment of a second wafer to the remaining chips of the first wafer, wafer-to-wafer bonding and performing chip-level fill of the bonded wafers. Software commands executed by CPU 472, may further cause system 400 to remove at least one chip from a wafer while retaining the relative positions/alignment of the remaining chips in the wafer and bond those remaining chips to a second wafer, as well as perform other processes in accordance with the present invention as described elsewhere herein (e.g., FIG. 1). Portions of the present invention may be provided as a computer program product, which may include a computer-readable medium having stored thereon instructions, which may be used to program a computer (or other electronic devices) to cause a system, such as system 400, to provide a first wafer having known good chips; provide a second wafer having known good chips; physically remove at least one chip from the second wafer while retaining, in the second wafer, the relative positions/alignment of the remaining chips; and join the chips remaining in the second wafer to the chips of the first wafer.

The computer-readable medium may include, but is not limited to, floppy diskettes, optical disks, CD-ROMs (compact disk read-only memory), and magneto-optical disks, ROMs (read-only memory), RAMs (random access memory), EPROMs (erasable programmable read-only memory), EEPROMs (electrically-erasable programmable read-only memory), magnet or optical cards, flash memory, or other commonly known type computer-readable medium suitable for storing electronic instructions. Moreover, the present invention may also be downloaded as a computer program product, wherein the program may be transferred from a remote computer to a requesting computer over a wire.

The present invention is not limited to wafer-to-wafer bonding on a single surface of the wafer. In accordance with an embodiment of the present invention, the methods described herein are used to bond both sides of a wafer, forming a multi-stacked structure.

A bonding process involving wafer-level bonding with chip-level removal and replacement may be used to bond members other than bonding a chip to a wafer. In accordance with another embodiment of the present invention, a bonding system incorporating the method described is used to bond two substrates of differing size, i.e., to bond a small substrate to a large substrate. In a particular embodiment, a bonding process involving methods described herein is used to bond a first wafer having a first diameter to a second wafer having a second diameter, wherein the first diameter is smaller than the second diameter.

What is claimed is:

1. A method of bonding for three dimensional packaging, comprising:
providing a first wafer comprising a first plurality of chips and a second wafer comprising a second plurality chips;
removing at least one of the second plurality of chips from the second wafer while retaining, in the second wafer, the relative positions of the remaining chips;
aligning the first wafer to the second wafer; and
joining the first wafer to the second wafer to join the remaining chips of the second plurality to corresponding chips of the first plurality.

2. The method of claim 1, wherein the at least one chip removed from the second wafer includes a bad chip having a relative physical position within the second wafer corresponding to a relative physical position of a good chip within the first wafer.

3. The method of claim 2, further comprising:
aligning a good chip to the first wafer at the relative position within the first wafer corresponding to the relative position of the bad chip within the second wafer; and
joining the good chip to the first wafer.

4. The method of claim 3, wherein the aligning of the good chip to the first wafer is performed after joining the first and second wafers.

5. The method of claim 1, wherein the at least one chip removed from the second wafer includes a good chip having a relative physical position within the second wafer corresponding to a relative physical position of a bad chip within the first wafer.

6. The method of claim 5, further comprising:
joining a nonfunctional chip to the first wafer at the relative position within the first wafer corresponding to the relative position of the good chip removed from second wafer.

7. The method of claim 1, wherein aligning the first wafer to the second wafer is performed after removing the at least one chip from the second wafer.

8. The method of claim 1, wherein retaining, in the second wafer, the relative positions of the remaining chips further comprises at least one of maintaining physical continuity of the remaining chips or maintaining a substantially continuous chucking force on individual portions of the second wafer before and after the removing of at the least one of the second plurality of chips.

9. The method of claim 1, wherein the second wafer is thinner or lower yielding than the first wafer.

10. The method of claim 1, further comprising sorting a population of candidate wafers to optimize a match of the yield patterns of the first and second wafer wafers, wherein the optimization is based on at least one of the number or the relative positions of the bad chips in the first and second wafers.

11. A wafer bonding system, comprising:
a first chuck to hold a first wafer comprising a first plurality of chips;
a second chuck to hold a second wafer comprising a second plurality of chips;
a removal means to remove at least one chip from the second wafer while retaining the relative positions of the remaining chips of the second plurality;
an alignment means to physically aligned the first wafer to the second wafer; and
a bonding means to join the first wafer to the second wafer after the at least one chip is removed from the second wafer.

12. The wafer bonding system of claim 11, wherein the second chuck further comprises a chuck segmented to control a chucking force independently across the second plurality of chips.

13. The wafer bonding system of claim 12, wherein the segmented chuck comprises a plurality of physically independent units capable of independent chucking and independent movement.

14. The wafer bonding system of claim 11, wherein the removal means further comprises:
a laser to circumscribe the at least one chip; and
a pick to remove the at least one chip from the second chuck.

15. The wafer bonding system of claim 11, further comprising:
an alignment means to physically align the first wafer to the second wafer after the at least one chip is physically removed from the second wafer; and wherein the bonding means is to join the first wafer to the second wafer.

16. The wafer bonding system of claim 11, further comprising:
an alignment means to physically align an individual chip to the first wafer after the at least one chip is physically removed from the second wafer; and wherein the bonding means is to join the good chip to the first wafer.

17. A computer readable medium having a set of instructions stored thereon which, when executed by a processor of a system, cause the system to perform a method, the method comprising:
providing a first wafer comprising a first plurality of chips and a second wafer comprising a second plurality chips;
removing at least one of the second plurality of chips from the second wafer while retaining, in the second wafer, the relative positions of the remaining chips;
aligning the first wafer to the second wafer; and
joining the first wafer to the second wafer to join the remaining chips of the second plurality to corresponding chips of the first plurality.

18. The computer readable medium of claim 17, wherein the at least one chip removed from the second wafer includes a bad chip having a relative physical position within the second wafer corresponding to a relative physical position of a good chip within the first wafer.

19. The computer readable medium of claim 17, further including instructions to perform the method comprising:
aligning a good chip to the first wafer at the relative position within the first wafer corresponding to the relative position of the bad chip within the second wafer; and
joining the good chip to the first wafer.

20. The computer readable medium of claim 16, wherein the at least one chip removed from the second wafer includes a good chip having a relative physical position within the second wafer corresponding to a relative physical position of a bad chip within the first wafer.
